(19) United States
(12) Patent Application Publication
(10) Pub. No.: US 2014/0179057 A1
(43) Pub. Date: Jun. 26, 2014

(54) METHOD FOR MANUFACTURING OXIDE SEMICONDUCTOR LAYER AND THIN FILM TRANSISTOR HAVING OXIDE SEMICONDUCTOR LAYER

(71) Applicant: HON HAI PRECISION INDUSTRY CO., LTD., New Taipei (TW)

(72) Inventor: JIAN-SHIHN TSANG, New Taipei (TW)

(73) Assignee: HON HAI PRECISION INDUSTRY CO., LTD., New Taipei (TW)

(21) Appl. No.: 13/974,033

(22) Filed: Aug. 22, 2013

(30) Foreign Application Priority Data
Dec. 25, 2012 (TW) 101149884

(51) Int. Cl. H01L 21/02; H01L 29/66; C23C 14/34

(52) U.S. Cl. CPC H01L 21/02565; C23C 14/34; H01L 29/66969; H01L 21/02631
USPC 438/104; 204/192.1

(57) ABSTRACT

A method for manufacturing an oxide semiconductor layer includes following steps: providing a substrate; forming an oxide semiconductor layer on the substrate by sputtering a first kind of metallic ions from a first metallic oxide sputtering target, and sputtering at least two second kinds of metallic ions from a second metallic oxide sputtering target. The at least two second kind of metallic ions are different from the first kind of metallic ions. A proportion of the first kind of metallic ions and the at least two second kind of metallic ions is adjustable by controlling a depositing speed of the oxide semiconductor layer and a period of using a baffle plate in sputtering. A method for manufacturing a thin film transistor is also provided.

### BACKGROUND

1. Technical Field

The disclosure generally relates to a method for manufacturing an oxide semiconductor layer and a method for manufacturing a thin film transistor having the oxide semiconductor layer.

2. Description of Related Art

Nowadays, thin film transistors have been widely used in display devices to make the display devices become thinner and smaller. A typical thin film transistor includes a channel layer, a gate electrode, a source electrode and a drain electrode formed on the channel layer. The thin film transistor is turned on or turned off by controlling a voltage applied to the gate electrode.

In manufacturing of traditional thin film transistor, the channel layer is formed by depositing of a single sputtering target material, which is selected from a group of InGaZnO₄, In₂Ga₂ZnO₇, In₂O₃(ZnO)ₘ (m=2-20). However, in the method described above, the material of the channel layer is directly determined by the sputtering target material, and can not be adjustable in the process of depositing. Therefore, a quality of the thin film transistor is affected.

What is needed, therefore, is a method for manufacturing an oxide semiconductor layer and a method for manufacturing a thin film transistor having the semiconductor layer to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an illustrating view of a method for manufacturing an oxide semiconductor layer in accordance with an embodiment of the present disclosure.

FIG. 2 is an illustrating view of the oxide semiconductor layer formed in FIG. 1.

FIG. 3 is an illustrating view of a method for manufacturing a thin film transistor having the oxide semiconductor layer in FIG. 2.

### DETAILED DESCRIPTION

Embodiments of an oxide semiconductor layer and a thin film transistor will now be described in detail below and with reference to the drawings.

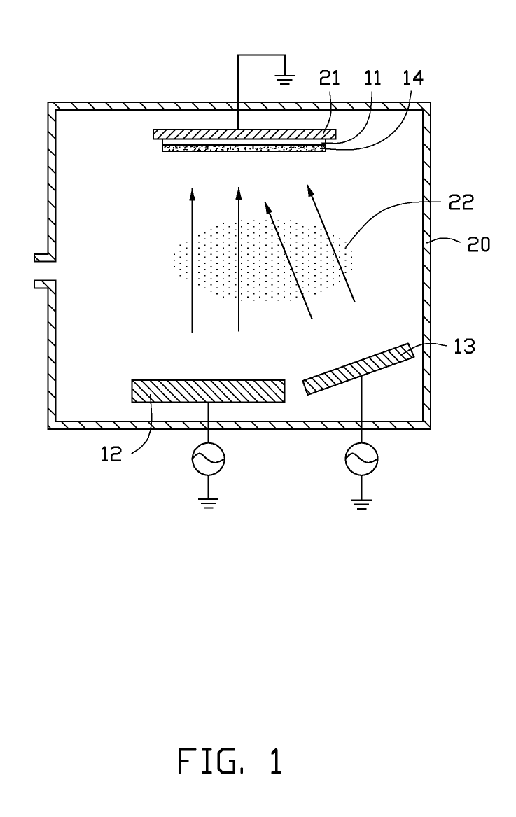

Referring to FIG. 1, a method for manufacturing an oxide semiconductor layer in accordance with an embodiment of the present disclosure is provided. The method includes following steps.

Firstly, a substrate 11 is provided. The substrate 11 is configured to support an oxide semiconductor layer in following steps. In this embodiment, the substrate 11 is made of a material selected from glass, quartz, silicon or plastic.

Secondly, an oxide semiconductor layer 14 is deposited on the substrate 11 by sputtering a first kind of metallic ions from a first metallic oxide sputtering target 12, and sputtering at least two second kinds of metallic ions from a second metallic oxide sputtering target 13. The two second kinds of metallic ions of the second metallic oxide sputtering target 13 are different from the first kind of metallic ions of the first metallic oxide sputtering target 12. In sputtering the metallic ions, a proportion of the first kind of metallic ions and the two second kinds of metallic ions is adjustable by controlling a depositing speed of the oxide semiconductor layer 14 and a period of using a baffle plate in sputtering.

The first metallic oxide sputtering target 12 includes a single kind of metallic ions. In this embodiment, the single kind of metallic ions of the first metallic oxide sputtering target 12 is selected from one of In, Ga, Zn and Sn.

The second metallic oxide sputtering target 13 includes two kinds of metallic ions. In this embodiment, the two kinds of metallic ions of the second metallic oxide sputtering target 13 are selected from two of In, Ga, Zn, Sn, Al, Ti, Ni, Mn, Mo, Cd and Cu.

The sputtering of the metallic ions can be processed by pulse laser deposition (PLD), or atomic layer deposition (ALD). In this embodiment, the substrate 11, the first metallic oxide sputtering target 12 and the second metallic oxide sputtering target 13 are positioned in a vacuum chamber 20 filled with inert gases. The substrate 11 is secured to a bracket 21. A high direct voltage is applied between the substrate 11 and the first metallic oxide sputtering target 12, and between the substrate 11 and the second metallic oxide sputtering target 13, thereby generating plasmas 22 in the inert gases by glow discharge. The plasmas 22 strike the metallic ions out of the first metallic oxide sputtering target 12 and the second metallic oxide sputtering target 13 to make the metallic ions deposit on the substrate 11.

The process of sputtering the first kind of metallic ions from the first metallic oxide sputtering target 12 on the substrate 11, and the process of sputtering the two second kinds of metallic ions from the second metallic oxide sputtering target 13 on the substrate 11 can be processed successively to form a crystal structure in a predetermined direction. Alternatively, the process of sputtering the first kind of metallic ions from the first metallic oxide sputtering target 12 on the substrate 11, and the process of sputtering the two second kinds of metallic ions from the second metallic oxide sputtering target 13 on the substrate 11 can be processed at the same time to form an oxide semiconductor layer with non-crystal structure.

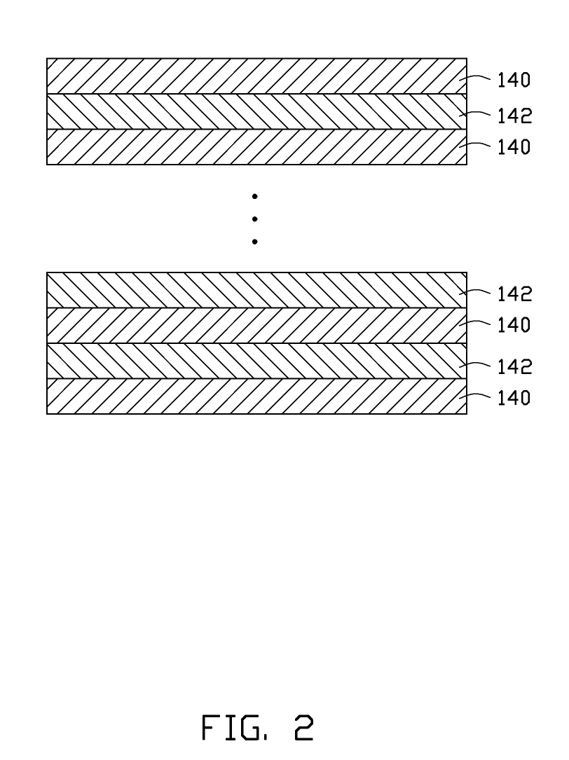

Referring to FIG. 2, the first metallic oxide sputtering target 12 is made of InO, and the second metallic oxide sputtering target 13 is made of ZnGaO. The process of sputtering the first kind of metallic ions from the first metallic oxide sputtering target 12 on the substrate 11, and the process of sputtering the two second kinds of metallic ions from the second metallic oxide sputtering target 13 on the substrate 11 are processed successively. Therefore, an InO layer 140 and a ZnGaO layer 142 are successively stacked on the substrate 11. The successively stack of the InO layer 140 and the ZnGaO layer 142 makes the oxide semiconductor layer 14 has a crystal structure in a direction vertical to a depositing surface of the substrate 11. Since a lattice constant of the InO layer 140 is mismatch to a lattice constant of the ZnGaO layer 142, the InO layer 140 is just bonded to two adjacent ZnGaO layers 142. Therefore, the proportion of the metallic ions of In and the metallic ions of Ga, Zn in the oxide semiconductor layer 14 can be effectively adjusted. Similarly, by adjusting the proportion of the metallic ions of Ga and the metal ions of Zn in the second metallic oxide sputtering target 13, the proportion of the metallic ions of Ga and the metal ions of Zn in the oxide semiconductor layer 14 is also adjustable.

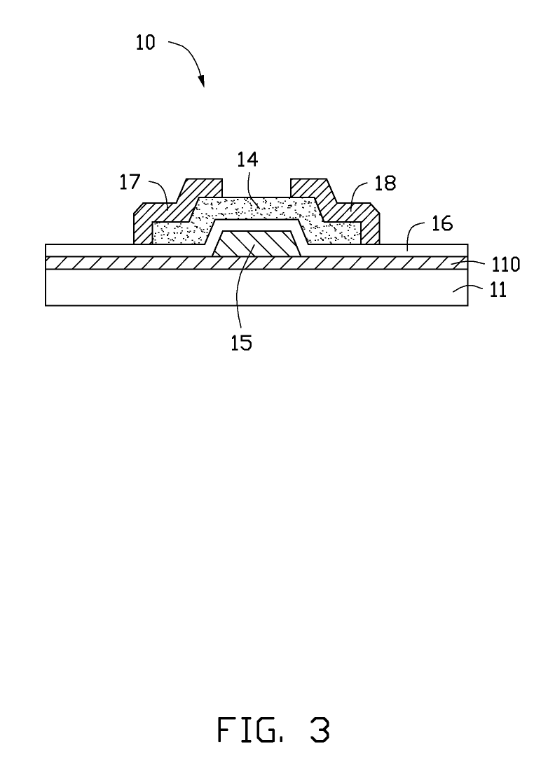

Referring to FIG. 3, a method for manufacturing a thin film transistor 10 is provided. The method includes following steps: forming a channel layer on the substrate 11 by the method described above; forming a gate electrode 15 on the channel layer, and the gate electrode 15 is separated from the channel layer by a gate insulating layer 16; forming a source electrode 17 on a first portion of the channel layer, and forming a drain electrode 18 on a second portion of the channel layer.

The channel layer formed on the substrate 11 is the oxide semiconductor layer 14. The gate electrode 15 of the thin film transistor 10 is formed on an insulation buffer layer 110 on the substrate 11. The gate insulating layer 16 is formed between the gate electrode 15 and the oxide semiconductor layer 14. The source electrode 17 is formed on a left side of the oxide semiconductor layer 14 and electrically connected with the left side of the oxide semiconductor layer 14. The drain electrode 18 is formed on a right side of the oxide semiconductor layer 14 and electrically connected with the right side of the oxide semiconductor layer 14.

In the method for manufacturing the oxide semiconductor layer 14 and the thin film transistor 10 described above, by using two different sputtering targets 12, 13 to deposit different kinds of metallic ions on the substrate 11, the proportion of the metallic ions in the oxide semiconductor layer 14 can be adjustable by controlling the depositing speed or using the baffle plate. Therefore, a quality of the thin film transistor 10 can be improved. In addition, since the first kind of metallic ions and the two second kinds of metallic ions are diffused uniformly in the oxide semiconductor layer 14, thin film transistors 10 having the oxide semiconductor layer 14 as a channel layer will have a relatively uniform distribution of threshold voltages.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing an oxide semiconductor layer, comprising following steps:
providing a substrate; and
forming an oxide semiconductor layer on the substrate by sputtering a first kind of metallic ions from a first metallic oxide sputtering target, and sputtering at least two second kinds of metallic ions from a second metallic oxide sputtering target, the at least two second kind of metallic ions being different from the first kind of metallic ions, and a proportion of the first kind of metallic ions and the at least two second kind of metallic ions being adjustable by controlling a depositing speed of the oxide semiconductor layer and a period of using a baffle plate in sputtering.

2. The method of claim 1, wherein the first metallic oxide sputtering target comprises a single kind of metallic ions.

3. The method of claim 2, wherein the single kind of metallic ions are selected from one of In, Ga, Zn and Sn.

4. The method of claim 1, wherein the second metallic oxide sputtering target comprises two kinds of metallic ions.

5. The method of claim 4, wherein the two kinds of metallic ions are selected from two of In, Ga, Zn, Sn, Al, Ti, Ni, Mn, Mo, Cd and Cu.

6. The method of claim 1, wherein the process of sputtering the first kind of metallic ions from the first metallic oxide sputtering target on the substrate, and the process of sputtering the two second kinds of metallic ions from the second metallic oxide sputtering target on the substrate are processed at the same time.

7. The method of claim 1, wherein the process of sputtering the first kind of metallic ions from the first metallic oxide sputtering target on the substrate, and the process of sputtering the two second kinds of metallic ions from the second metallic oxide sputtering target on the substrate are processed successively.

8. The method of claim 1, wherein the metal ions are sputtered on the substrate by pulse laser deposition (PLD), or atomic layer deposition (ALD).

9. A method for manufacturing a thin film transistor, comprising following steps:
providing a substrate;
forming a channel layer on the substrate by sputtering a first kind of metallic ions from a first metallic oxide sputtering target, and sputtering at least two second kinds of metallic ions from a second metallic oxide sputtering target, the at least two second kind of metallic ions being different from the first kind of metallic ions, and a proportion of the first kind of metallic ions and the at least two second kind of metallic ions being adjustable by controlling a depositing speed of the channel layer and a period of using a baffle plate in sputtering;
forming a gate electrode on the channel layer, the gate electrode being separated from the channel layer by a gate insulating layer;
forming a source electrode electrically connected with a first portion of the channel layer; and
forming a drain electrode electrically connected with a second portion of the channel layer.

10. The method of claim 9, wherein the channel layer is made of InGaZnO.

11. The method of claim 9, wherein the first metallic oxide sputtering target comprises a single kind of metallic ions.

12. The method of claim 11, wherein the single kind of metallic ions are selected from one of In, Ga, Zn and Sn.

13. The method of claim 9, wherein the second metallic oxide sputtering target comprises two kinds of metallic ions.

14. The method of claim 13, wherein the two kinds of metallic ions are selected from two of In, Ga, Zn, Sn, Al, Ti, Ni, Mn, Mo, Cd and Cu.

15. The method of claim 9, wherein the process of sputtering the first kind of metallic ions from the first metallic oxide sputtering target on the substrate, and the process of sputtering the two second kinds of metallic ions from the second metallic oxide sputtering target on the substrate are processed at the same time.

16. The method of claim 9, wherein the process of sputtering the first kind of metallic ions from the first metallic oxide sputtering target on the substrate, and the process of sputtering the two second kinds of metallic ions from the second metallic oxide sputtering target on the substrate are processed successively.

17. The method of claim 9, wherein the metal ions are sputtered on the substrate by pulse laser deposition (PLD), or atomic layer deposition (ALD).
